(19) United States
(12) Patent Application Publication
(10) Pub. No.: US 2025/0379171 A1
(43) Pub. Date: Dec. 11, 2025

(54) Semiconductor Chip with Interconnects and Method for Manufacturing the Same

(71) Applicant: Taiwan Semiconductor Manufacturing Company, Ltd., Hsinchu (TW)

(72) Inventors: Shenggao Li, Hsinchu (TW); Mu-Shan Lin, Hsinchu (TW); Wen-Hung Huang, Hsinchu (TW)

(21) Appl. No.: 18/912,708

(22) Filed: Oct. 11, 2024

Related U.S. Application Data
(60) Provisional application No. 63/656,246, filed on Jun. 5, 2024.

(51) Int. Cl. H01L 23/00; H01L 25/065

(52) U.S. Cl. CPC H01L 24/14; H01L 24/11; H01L 24/16; H01L 25/0657; H01L 24/13; H01L 2224/118; H01L 2224/13147; H01L 2224/14131; H01L 2224/16145; H01L 2224/16225; H01L 2225/06513; H01L 2924/37001

(57) ABSTRACT

A system includes a semiconductor chip and a plurality of interconnects. The semiconductor chip has a bottom or top surface divided into two or more zones. The interconnects are formed over the zones. The interconnects in each zone are arranged in an array of rows. Each interconnect in a first zone is connected to a respective first interconnect in a fourth zone. The interconnects from top to bottom rows in the first zone are symmetric with the interconnects from bottom to top rows in the fourth zone about the y-axis. Each interconnect in a second zone is connected to a respective interconnect in a third zone. The interconnects from top to bottom rows in the second zone are symmetric with the interconnects from bottom to top rows in the third zone about the y-axis.

### CROSS-REFERENCE TO RELATED APPLICATION

The present application claims priority to U.S. Provisional Application No. 63/656,246, filed Jun. 5, 2024, the contents of which are incorporated by reference herein in its entirety.

### BACKGROUND

Packaging technologies, such as three-dimensional integrated circuit (3D-IC) technologies, involve stacking semiconductor chips on top of each other. This arrangement can enhance performance while reducing the surface area occupied by the semiconductor chips on the package substrate.

### BRIEF DESCRIPTION OF THE DRAWINGS

Aspects of the present disclosure are best understood from the following detailed description when read with the accompanying figures:

FIG. 1 is a sectional view illustrating semiconductor chips of a system in accordance with various embodiments of the present disclosure;

FIG. 2 is a sectional view illustrating another semiconductor chips of the system in accordance with various embodiments of the present disclosure;

FIG. 3 is a sectional view illustrating another semiconductor chip and an interposer of the system in accordance with various embodiments of the present disclosure;

FIG. 4 is a schematic bottom (or top) view illustrating another semiconductor chip of the system in accordance with various embodiments of the present disclosure;

FIG. 5 is a schematic bottom (or top) view illustrating another semiconductor chip of the system in accordance with various embodiments of the present disclosure;

FIG. 6 is a schematic bottom (or top) view illustrating another semiconductor chip of the system in accordance with various embodiments of the present disclosure;

FIG. 7 is a schematic bottom (or top) view illustrating another semiconductor chip of the system in accordance with various embodiments of the present disclosure;

FIG. 8 is a schematic bottom (or top) view illustrating another semiconductor chip of the system in accordance with various embodiments of the present disclosure;

FIG. 9 is a schematic bottom (or top) view illustrating another semiconductor chip of the system in accordance with various embodiments of the present disclosure;

FIG. 10 is a schematic bottom (or top) view illustrating another semiconductor chip of the system in accordance with various embodiments of the present disclosure;

FIG. 11 is a schematic bottom (or top) view illustrating another semiconductor chip of the system in accordance with various embodiments of the present disclosure;

FIG. 12 is a schematic bottom (or top) view illustrating another semiconductor chip of the system in accordance with various embodiments of the present disclosure;

FIG. 13 is a schematic bottom (or top) view illustrating another semiconductor chip of the system in accordance with various embodiments of the present disclosure; and

FIG. 14 is a flowchart illustrating a method of manufacturing the system in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Systems and methods herein describe three-dimensional integrated circuit (3D-IC) technologies and other packing technologies that can involve stacking semiconductor chips (e.g., integrated circuits or semiconductor dies) on top of each other, which can enhance performance while reducing a surface area of a package substrate, an interposer, or printed circuit board (PCB) occupied by the semiconductor chips.

Interconnects create electrical connection between stacked semiconductor chips or between a semiconductor chip and a package substrate, an interposer, or a PCB. Such interconnects include micro-bumps, solder balls, copper pillars, a ball grid array (BGA), a combination of metal and dielectric interconnects, other interconnects created by, e.g., metal-to-metal bonding, dielectric-to-dielectric bonding, tape-automated bonding (TAB), wire bonding, or flip-chip bonding, other suitable interconnects, or combinations thereof.

In certain examples, during manufacturing of a system using a packaging technology, when bonding semiconductor chips to each other, the interconnects of one semiconductor chip may be aligned with the interconnects of the other semiconductor chip. This process can be prone to errors. For example, a semiconductor chip may be inadvertently rotated about an axis perpendicular to its surface, resulting in a bonding error between the semiconductor chips. Such a bonding error can connect an interconnect that transmits a data signal to another interconnect that also transmits a data signal, instead of one intended to receive a data signal, resulting in a data communication error between semiconductor chips.

Systems and methods as described in certain examples herein mitigate this issue by, in some examples, symmetrically arranging interconnects of a semiconductor chip. This approach can reduce, if not eliminate, bonding errors due to inadvertent rotation of a semiconductor chip, thereby increasing the manufacturing yield of the system. For example, in some designs, symmetric interconnects can make a semiconductor chip resilient to incorrect orientations during bonding (e.g., 90 degrees, 180 degrees, 270 degrees rotation from the intended orientation) or can make a semiconductor chip agnostic as to its orientation during bonding as long as interconnects are properly made.

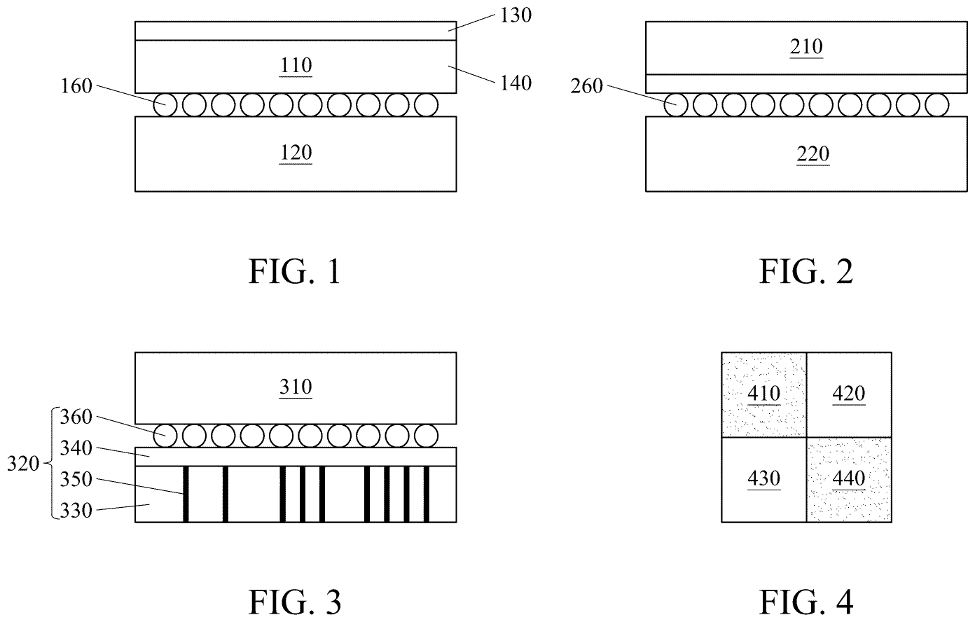

In further detail, FIG. 1 is a sectional view illustrating semiconductor chips 110, 120 of a system (e.g., a 3D-IC system or other packaging technology systems) in accordance with various embodiments of the present disclosure. As illustrated in FIG. 1, the semiconductor chip 110 includes a chip substrate 130, a chip circuit 140, and a plurality of interconnects 160. Examples of materials for the chip substrate 130 include silicon, germanium, III-V semiconductor materials, other suitable semiconductor material, and combinations thereof. The chip circuit 140 is fabricated over the chip substrate 130 and performs one or more circuit functions. In one example, the chip circuit 140 includes a plurality of chip components, e.g., passive chip components (such as resistors, inductors, and capacitors) and/or active chip components (such as transistors, diodes, and integrated circuits). In such one example, the chip circuit 140 further includes a conductive layer (e.g., back end of line or BEOL) that interconnects the chip components and that has horizontal and vertical metal lines.

The interconnects 160 are formed over the top surface of the semiconductor chip 110 and connected to the conductive layer. In certain embodiments, the interconnects 160 include micro-bumps, solder balls, copper pillars, a BGA, a combination of metal and dielectric interconnects, other interconnects created by, e.g., metal-to-metal bonding, dielectric-to-dielectric bonding, TAB, wire bonding, or flip-chip bonding, other suitable interconnects, or combinations thereof. The semiconductor chip 120 has a similar structure as the semiconductor chip 110 and, in this exemplary embodiment, is bonded to the top surface of the semiconductor chip 110 through the interconnects 160. In an embodiment, the conductive layer and interconnects of the semiconductor chip 110 are made from copper, aluminum, nickel, barrier metals (e.g., titanium, tungsten, and tantalum), gold, tin, other suitable conductive material, or an alloy thereof.

FIG. 2 is a sectional view illustrating another semiconductor chips 210, 220 of the system in accordance with various embodiments of the present disclosure. As illustrated in FIG. 2, the semiconductor chip 210, 220 differs from the semiconductor chip 110, 120 in that the interconnects 260 are formed over, instead of the top surface, the bottom surface of the semiconductor chip 210. In this exemplary embodiment, the semiconductor chip 220 is bonded to the bottom surface of the semiconductor chip 210 through the interconnects 260.

FIG. 3 is a sectional view illustrating a semiconductor chip 310 and an interposer 320 of another system in accordance with various embodiments of the present disclosure. As illustrated in FIG. 3, the semiconductor chip 310 differs from the semiconductor chip 110, 210 in that the semiconductor chip 310 is bonded to an interposer 320 through the interconnects 360 thereof. The interposer 320 includes an interposer substrate 330, a front-side redistribution layer (RDL) 340, and one or more through-interposer vias (TIVs) 350. Examples of materials for the interposer substrate 330 include silicon, organic materials, glass, ceramics, polymer-based materials, other suitable interposer substrate materials, and combinations thereof. The front-side RDL 340 is formed over the top surface of the interposer 320 and includes horizontal and vertical metal lines. Each TIV 350 extends from the RDL 240 to the bottom surface of the interposer 320.

In an alternative embodiment, the interposer 320 further includes a back-side RDL formed over the bottom surface of the interposer 320. In such an alternative embodiment, the TIV 350 is connected between the front-and back-side RDLs 340. Examples of materials for the front-and back-side RDLs 340 and the TIVs 350 include copper, nickel, gold, silver, cobalt, tungsten, aluminum, other conductive materials, and combinations thereof.

FIG. 4 is a schematic bottom (or top) view illustrating a semiconductor chip 400 of the system in accordance with various embodiments of the present disclosure. As illustrated in FIG. 4, the semiconductor chip 400, e.g., semiconductor chip 110, 210, 310, has a bottom (or top) surface divided into two or more zones, e.g., quadrants 410-440, and a plurality of interconnects, e.g., interconnects 160, 260, 360, formed over the quadrants 410-440. In this exemplary embodiment, the interconnects in the quadrant 440 are symmetric with the interconnects in the quadrant 410, whereas the interconnects in the quadrant 430 are symmetric with the interconnects in the quadrant 420. The construction as such of the semiconductor chip 400 may facilitate correct bonding of the semiconductor chip 400 to another semiconductor chip (e.g., semiconductor chip 110, 220), an interposer (e.g., interposer 320), a package substrate, or a PCB of the system, as will be describe in detail hereinafter.

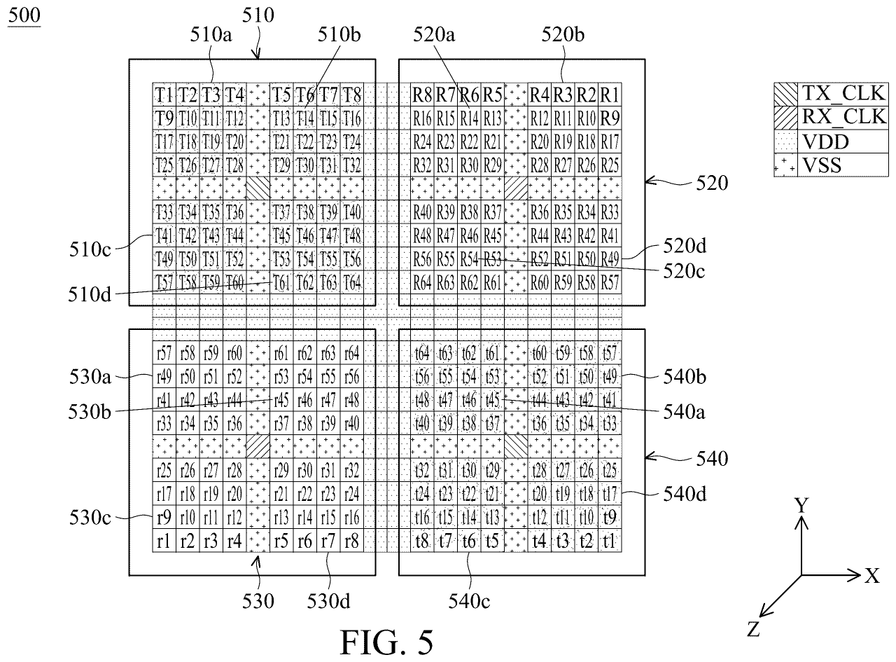

FIG. 5 is a schematic bottom (or top) view illustrating another semiconductor chip 500 of the system in accordance with various embodiments of the present disclosure. As illustrated in FIG. 5, the semiconductor chip 500 (e.g., semiconductor chip 110, 210, 310), has a bottom (or top) surface divided into two or more zones (e.g., quadrants 510-540) and includes a plurality of interconnects formed over these quadrants 510-540. In this exemplary embodiments, the interconnects include transmit signal (T1-T64, t1-t64) interconnects, receive signal (R1-64, r1-r64) interconnects, clock signal (TX_CLK, RX_CLK) interconnects, supply voltage (VDD) interconnects, and reference voltage (VSS) interconnects.

In this exemplary embodiment, the supply voltage (VDD) interconnects receive a supply voltage (VDD), define the quadrants 510-540, and lie along the x- and y-axes. In one example, the supply voltage (VDD) interconnects are symmetric with respect to the x- and y-axes. The reference voltage (VSS) interconnects receive a reference voltage (VSS) (or are connected to ground), further divide each zone into two or more sub-zones, e.g., sub-quadrants 510a-510d, 520a-520d, 530a-530d, 540a-540d, and lie along the x- and y-axes. In one example, the reference voltage (VSS) interconnects are symmetric with respect to the x- and y-axes.

The clock signal (TX_CLK) interconnect in each quadrant 510, 540 transmits a clock signal (TX_CLK) and, in one example, is disposed at the intersection of the x- and y-axes. The receive clock signal (RX_CLK) interconnect in each quadrant 520, 530 receives a clock signal (RX_CLK) and, in one example, is disposed at the intersection of the x- and y-axes. The transmit signal (T1-T8, T9-T16, T17-T32, T33-T40, T41-T48, T49-T56, T57-T64) interconnects in the quadrant 510, each transmitting a distinct transmit signal (e.g., data signal) (T1-T8, T9-T16, T17-T32, T33-T40, T41-T48, T49-T56, T57-T64), are arranged in an array of rows, and are ordered from top to bottom. The transmit signal (t1-t8, t9-t16, t17-t32, t33-t40, t41-t48, t49-t56, t57-t64) interconnects in the quadrant 540, each connected to the respective transmit signal (T1-T8, T9-T16, T17-T32, T33-T40, T41-T48, T49-T56, T57-T64) interconnects, are arranged in an array of rows, and are ordered from bottom to top. In one example, the transmit signal (t1-t8, t9-t16, t17-t32, t33-t40, t41-t48, t49-t56, t57-t64) interconnects are symmetric with the transmit signal (T1-T8, T9-T16, T17-T32, T33-T40, T41-T48, T49-T56, T57-T64) interconnects about the y-axis.

Similarly, the receive signal (R1-R8, R9-R16, R17-R32, R33-R40, R41-R48, R49-R56, R57-R64) interconnects in the quadrant 520, each receiving a distinct receive signal (e.g., data signal) (R1-R8, R9-R16, R17-R32, R33-R40, R41-R48, R49-R56, R57-R64), are arranged in an array of rows, and are ordered from top to bottom. The receive signal (r1-r8, r9-r16, r17-r32, r33-r40, r41-r48, r49-r56, r57-r64) interconnects in the quadrant 530, each connected to the respective receive signal (R1-R8, R9-R16, R17-R32, R33-R40, R41-R48, R49-R56, R57-R64) interconnects, are arranged in an array of rows, and are ordered from bottom to top. In one example, the receive signal (r1-r8, r9-r16, r17-r32, r33-r40, r41-r48, r49-r56, r57-r64) interconnects are symmetric with the receive signal (R1-R8, R9-R16, R17-R32, R33-R40, R41-R48, R49-R56, R57-R64) interconnects about the y-axis.

From the above description, the interconnects of the semiconductor chip 500 are symmetrically arranged. Such symmetry facilitates correct bonding of the semiconductor chip 500 to another semiconductor chip, a package substrate, an interposer, or a PCB. For example, as will be described hereinafter, each transmit signal (T1-T64, t1-t64) interconnect of a semiconductor chip can be correctly connected to a respective receive signal (R1-R64, r1-r64) interconnect of another semiconductor chip even if either of the semiconductor chips is rotated about an axis transverse to the x- and y-axes.

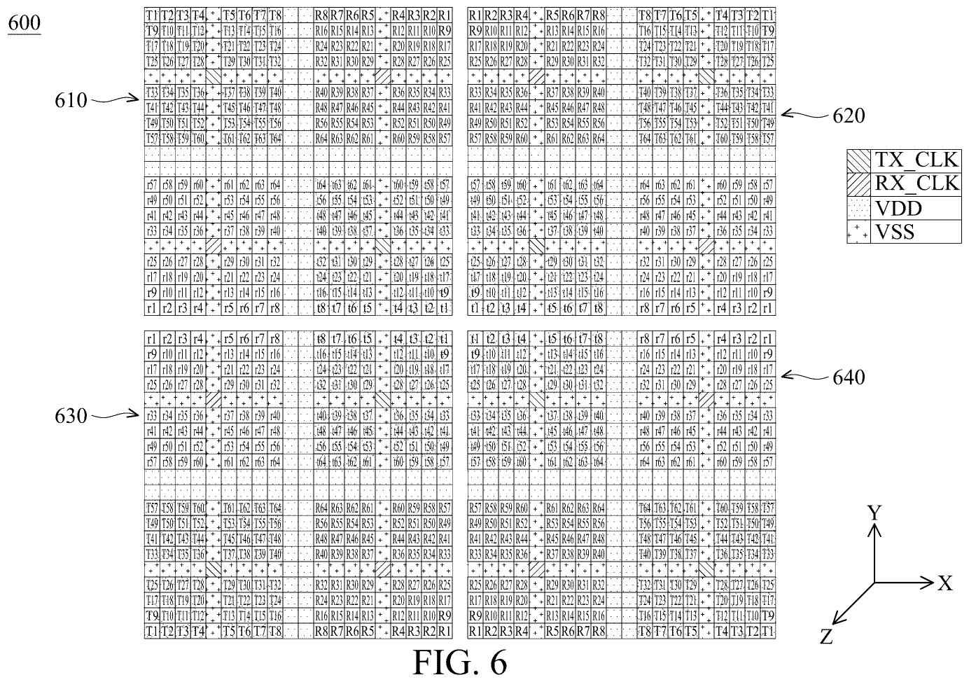

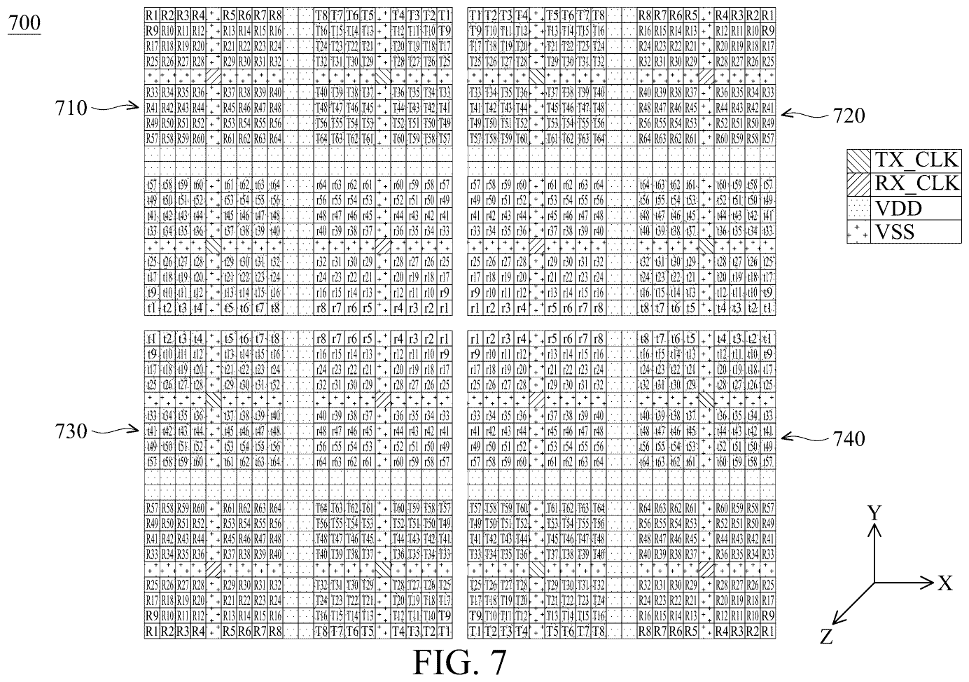

FIGS. 6 and 7 are schematic bottom (or top) views illustrating another semiconductor chips 600, 700 of the system in accordance with various embodiments of the present disclosure. As illustrated in FIG. 6 or 7, the semiconductor chip 600, 700 (e.g., semiconductor chip 110, 210, 310) has a bottom (or top) surface divided into two or more zones (e.g., quadrants 610-640, 710-740) and includes a plurality of interconnects formed over these quadrants 610-640, 710-740. In certain embodiments, the quadrants 610-640, 710-740 are at the top-left corner, the top-right corner, the bottom-left corner, and the bottom-right corner of the semiconductor chip 600, 700, respectively. The interconnects include transmit signal (T1-T64, t1-t64) interconnects, receive signal (R1-64, r1-r64) interconnects, clock signal (TX_CLK, RX_CLK) interconnects, supply voltage (VDD) interconnects, and reference voltage (VSS) interconnects.

In this exemplary embodiment, as illustrated in FIG. 6, the interconnects in quadrant 610 are identical to the interconnects of the semiconductor chip 500. The interconnects in the quadrant 620 are symmetric with the interconnects in the quadrant 610 about the y-axis. The interconnects in the quadrant 630 are symmetric with the interconnects in the quadrant 610 about the x-axis. The interconnects in the quadrant 640 are symmetric with the interconnects in the quadrant 630 about the y-axis.

As illustrated in FIG. 7, the interconnects in the quadrant 720 are identical to the interconnects of the semiconductor chip 500. The interconnects in the quadrant 710 are symmetric with the interconnects in the quadrant 720 about the y-axis. The interconnects in the quadrant 730 are symmetric with the interconnects in the quadrant 710 about the x-axis. The interconnects in the quadrant 740 are symmetric with the interconnects in the quadrant 730 about the y-axis.

From the above description of the semiconductor chips 600, 700, when it is desired to bond the semiconductor chip 600 to the semiconductor chip 700, the interconnects of the semiconductor chip 600 are aligned with and connected to the interconnects of the semiconductor chip 700 without flipping the semiconductor chip 600. This process correctly bonds the semiconductor chip 600 to the semiconductor chip 700 even if the semiconductor chip 600 is rotated about an axis transverse to the x- and y-axes by 180° and/or is flipped about the x- or y-axes.

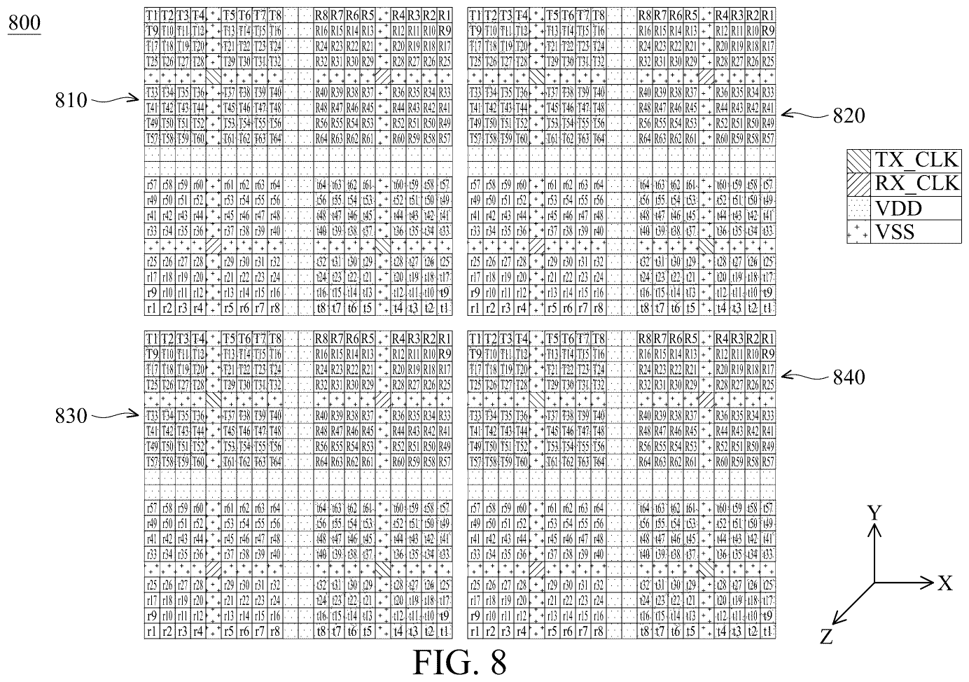

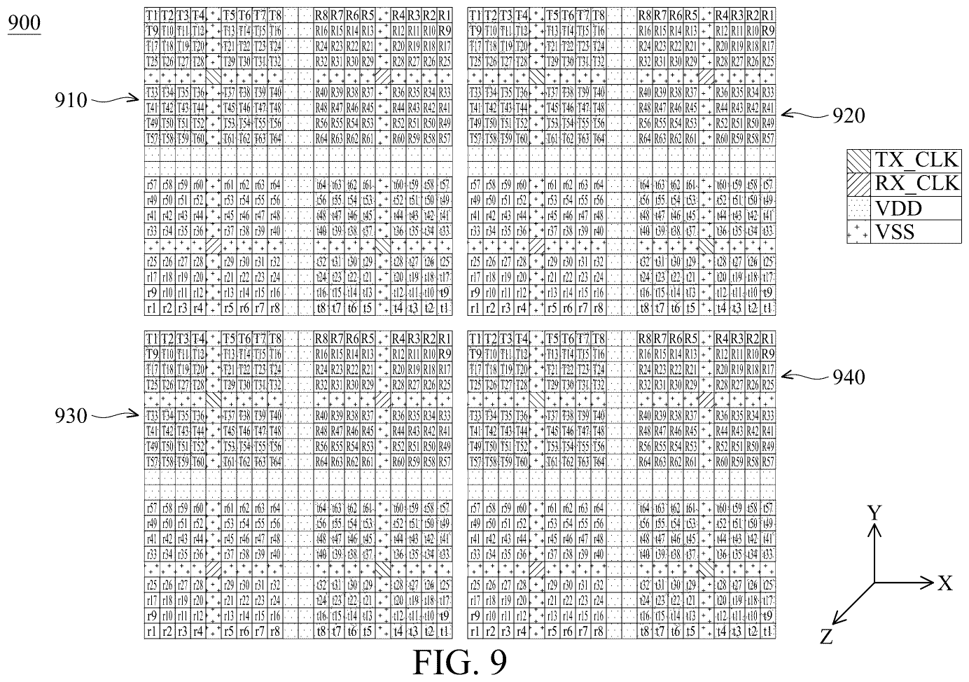

FIGS. 8 and 9 are schematic bottom (or top) views illustrating another semiconductor chips 800, 900 of the system in accordance with various embodiments of the present disclosure. As illustrated in FIG. 8 or 9, the semiconductor chip 800, 900 (e.g., semiconductor chip 110, 210, 310) has a bottom (or top) surface divided into two or more zones (e.g., quadrants 810-840, 910-940) and includes a plurality of interconnects formed over these quadrants 810-840, 910-940. In certain embodiments, the quadrants 810-840, 910-940 are at the top-left corner, the top-right corner, the bottom-left corner, and the bottom-right corner of the semiconductor chip 800, 900, respectively. The interconnects include transmit signal (T1-T64, t1-t64) interconnects, receive signal (R1-64, r1-r64) interconnects, clock signal (TX_CLK, RX_CLK) interconnects, supply voltage (VDD) interconnects, and reference voltage (VSS) interconnects. In this exemplary embodiment, as illustrated in FIGS. 8 and 9, the interconnects in quadrants 810-840, 910-940 are identical to the interconnects of the semiconductor chip 500.

From the above description of the semiconductor chips 800, 900, when it is desired to bond the semiconductor chip 800 to the semiconductor chip 900, the semiconductor chip 800 is flipped about the x- or y-axis and the interconnects thereof are aligned with and connected to the interconnects of the semiconductor chip 900 without rotating the semiconductor chip 800 about an axis transverse to the x- and y-axes. This process correctly bonds the semiconductor chip 800 to the semiconductor chip 900 even if the semiconductor chip 800 is rotated about an axis transverse to the x- and y-axes by 180°.

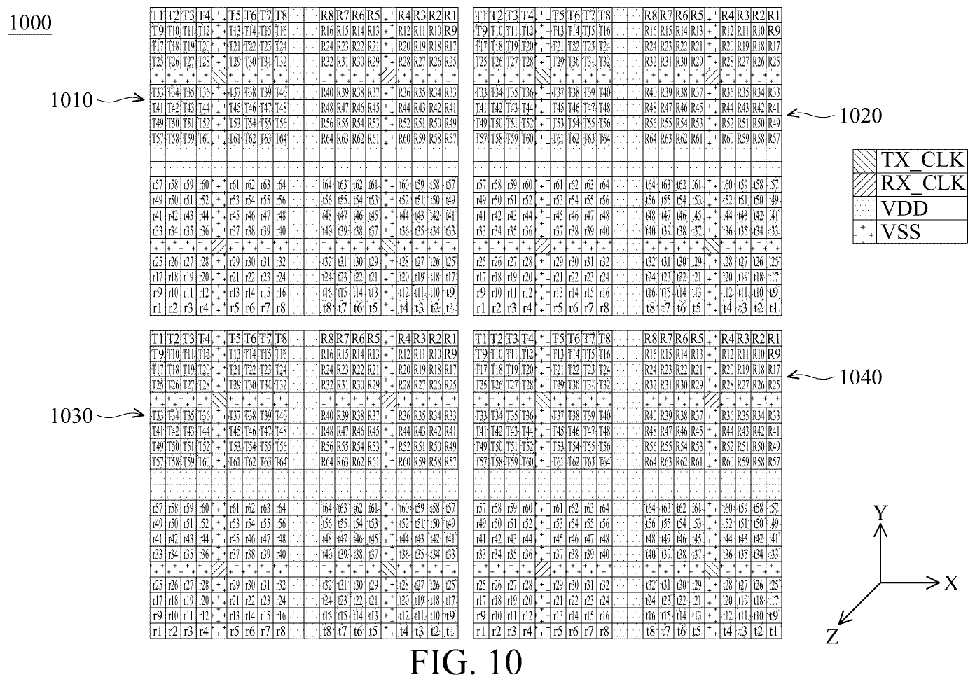

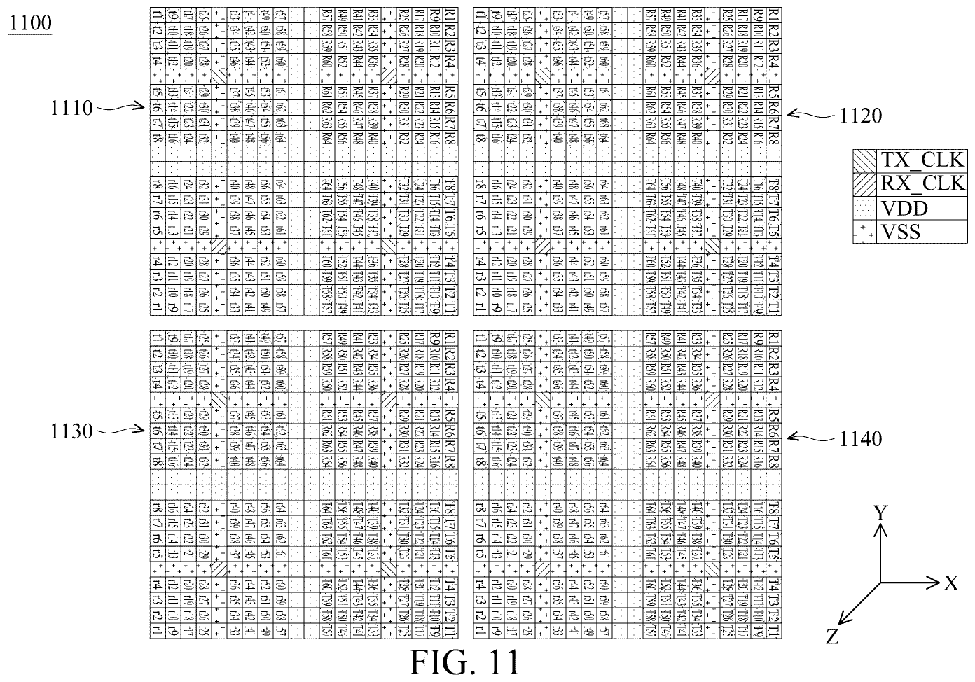

FIGS. 10 and 11 are schematic bottom (or top) views illustrating another semiconductor chips 1000, 1100 of the system in accordance with various embodiments of the present disclosure. As illustrated in FIG. 10 or 11, the semiconductor chip 1000, 1100 (e.g., semiconductor chip 110, 210, 310) has a surface divided into two or more zones (e.g., quadrants 1010-1040, 1110-1140) and includes a plurality of interconnects formed over these quadrants 1010-1040, 1110-1140. In this exemplary embodiment, the quadrants 1010-1040, 1110-1140 are at the top-left corner, the top-right corner, the bottom-left corner, and the bottom-right corner of the semiconductor chip 1000, 1100, respectively. The interconnects include transmit signal (T1-T64, t1-t64) interconnects, receive signal (R1-64, r1-r64) interconnects, clock signal (TX_CLK, RX_CLK) interconnects, supply voltage (VDD) interconnects, and reference voltage (VSS) interconnects.

In certain embodiments, as illustrated in FIG. 10, the interconnects in quadrants 1010-1040 are identical to the interconnects of the semiconductor chip 500. As illustrated in FIG. 11, the interconnects in the quadrant 1110 are symmetric with the interconnects of the semiconductor chip 500 after the semiconductor chip 500 is rotated about an axis transverse to x- and y-axes. The interconnects in the quadrants 1120-1140 are identical to the interconnects in the quadrant 1110.

From the above description of the semiconductor chips 1000, 1100, when it is desired to bond the semiconductor chip 1000 to the semiconductor chip 1100, the semiconductor chip 1000 is rotated about an axis transverse to the x- and y-axes by 90° and the interconnects thereof are aligned with and connected to the interconnects of the semiconductor chip 1100. This process correctly bonds the semiconductor chip 1000 to the semiconductor chip 1100 even if the semiconductor chip 1000 is rotated about an axis transverse to the x- and y-axes by 270°.

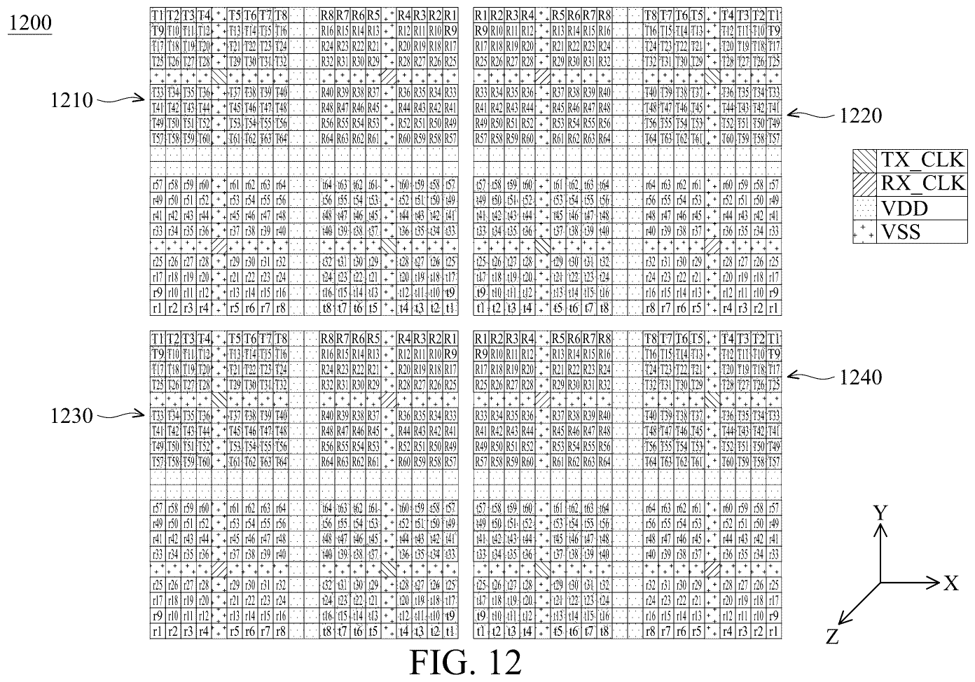

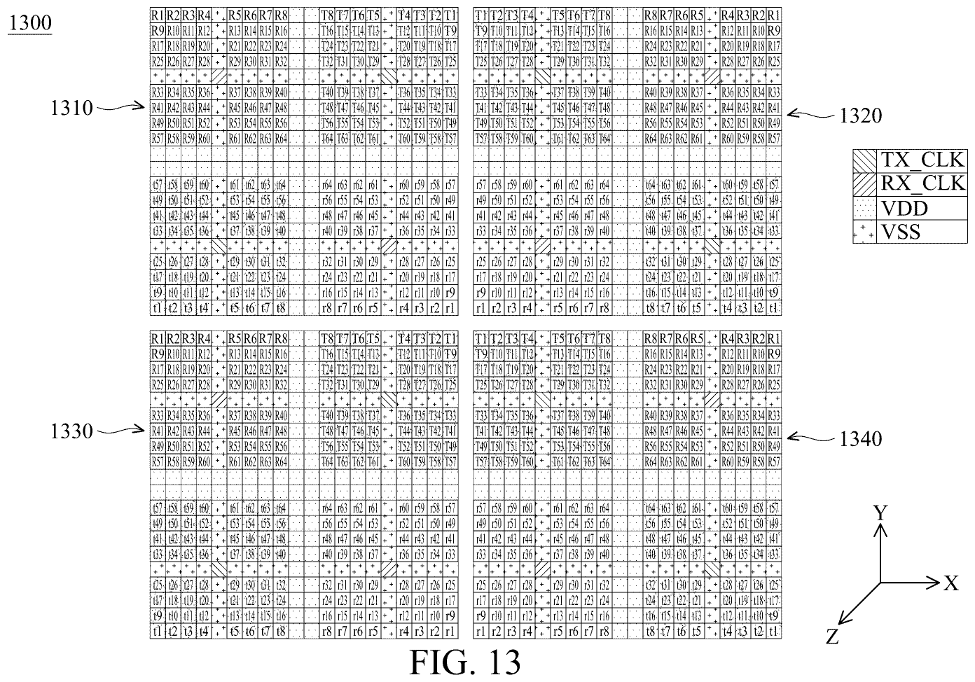

FIGS. 12 and 13 are schematic bottom (or top) views of the system illustrating another exemplary semiconductor chips 1200, 1300 of the system in accordance with various embodiments of the present disclosure. As illustrated in FIG. 12 or 13, the semiconductor chip 1200, 1300 (e.g., semiconductor chip 110, 210, 310) has a bottom (or top) surface divided into two or more zones (e.g., quadrants 1210-1240, 1310-1340) and includes a plurality of interconnects formed over these quadrants 1210-1240, 1310-1340. In certain embodiments, the quadrants 1210-1240, 1310-1340 are at the top-left corner, the top-right corner, the bottom-left corner, and the bottom-right corner of the semiconductor chip 1200, 1300, respectively. The interconnects include transmit signal (T1-T64, t1-t64) interconnects, receive signal (R1-64, r1-r64) interconnects, clock signal (TX_CLK, RX_CLK) interconnects, supply voltage (VDD) interconnects, and reference voltage (VSS) interconnects.

In this exemplary embodiment, as illustrated in FIG. 12, the interconnects in quadrants 1210 are identical to the interconnects of the semiconductor chip 500. The interconnects in the quadrant 1220 are symmetric with the interconnects in the quadrant 1210 about the y-axis. The interconnects in the quadrant 1230 are identical to the interconnects in the quadrant 1210. The interconnects in the quadrant 1240 are symmetric with the interconnects in the quadrant 1230 about the y-axis.

As illustrated in FIG. 13, the interconnects in quadrant 1320 are identical to the interconnects of the semiconductor chip 500. The interconnects in the quadrant 1310 are symmetric with the interconnects in the quadrant 1320. The interconnects in the quadrant 1330 are identical to the interconnects in the quadrant 1310. The interconnects in the quadrant 1340 are symmetric with the interconnects in the quadrant 1330 about the y-axis.

From the above description of the semiconductor chips 1200, 1300, when it is desired to bond the semiconductor chip 1200 to the semiconductor chip 1300, the interconnects of the semiconductor chip 1200 are aligned with and connected to the interconnects of the semiconductor chip 1300 without rotating or flipping the semiconductor chip 1200. This process correctly bonds the semiconductor chip 1200 to the semiconductor chip 1300 even if the semiconductor chip 1200 is flipped about the y-axis.

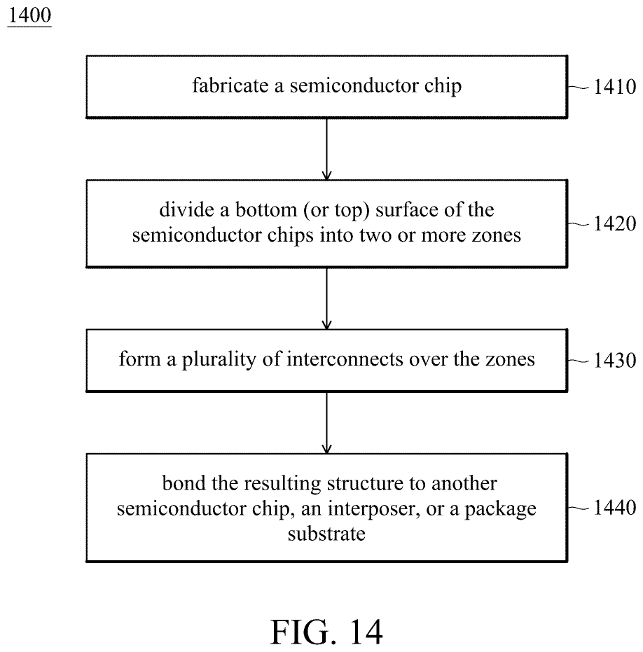

FIG. 14 is a flowchart illustrating a method 1400 of manufacturing the system in accordance with various embodiments of the present disclosure. The example method 1400 will now be described with further reference to FIGS. 1-13 for ease of understanding. It is understood that the method 1400 is applicable to structures other than those of FIGS. 1-13. Further, it is understood that additional operations can be provided before, during, and after the method 1400, and some of the operations described below can be replaced or eliminated, in an alternative embodiment of the method 1400.

In operation 1410, the system manufacturing equipment fabricates a semiconductor chip (e.g., semiconductor chip 110, 210, 310, and 400-1300). In certain embodiments, the operation 1010 includes: receiving a chip substrate and forming a chip circuit over the chip substrate. The chip circuit performs one or more circuit functions and includes chip components, e.g., one or more active components (such as transistors, diodes, and integrated circuits) and/or one or more passive components (such as resistors, inductors, and capacitors). In such certain embodiments, the operation 1010 further includes: interconnecting the chip components using a conductive layer, e.g., BEOL, and forming one or more through-substrate vias (TSVs) that extends from the conductive layer to the bottom surface of the chip substrate. In one example, the interconnects include micro-bumps, solder balls, copper pillars, a BGA, a combination of metal and dielectric interconnects, other interconnects created by, e.g., metal-to-metal bonding, dielectric-to-dielectric bonding, TAB, wire bonding, or flip-chip bonding, other suitable interconnects, or combinations thereof.

In operation 1420, the system manufacturing equipment divides the bottom (or top) surface of the semiconductor chip, e.g., semiconductor chip 500, into one or more zones (e.g., quadrants 510-540). Operation 1430 includes: forming interconnects over the quadrants 510-540. The interconnects include transmit signal (T1-T64, t1-t64) interconnects, receive signal (R1-64, r1-r64) interconnects, clock signal (TX_CLK, RX_CLK) interconnects, supply voltage (VDD) interconnects, and reference voltage (VSS) interconnects. In operation 1440, the system manufacturing equipment bonds the semiconductor chip 500 to another semiconductor chip (e.g., semiconductor chip 120), an interposer (e.g., interposer 320), a package substrate, or a PCB.

In an embodiment, a system comprises a plurality of semiconductor chips stacked on top of each other. The plurality of semiconductor chips include a semiconductor chip and a plurality of interconnects. The semiconductor chip has a bottom or top surface divided into two or more zones. The interconnects are formed over the zones. The interconnects in each zone are arranged in an array of rows. Each interconnect in a first zone is connected to a respective first interconnect in a fourth zone. The interconnects from top to bottom rows in the first zone are symmetric with the interconnects from bottom to top rows in the fourth zone about the y-axis. Each interconnect in a second zone is connected to a respective interconnect in a third zone. The interconnects from top to bottom rows in the second zone are symmetric with the interconnects from bottom to top rows in the third zone about the y-axis.

In another embodiment, a semiconductor chip comprises a chip substrate, a chip circuit, a conductive layer, a plurality of first interconnects, a plurality of second interconnects, a plurality of third interconnects, and a plurality of fourth interconnects. The chip circuit is fabricated over the chip substrate and performs one or more circuit functions. The conductive layer interconnects chip components of the chip circuit. The first interconnects are formed over a first zone of a bottom or top surface of the semiconductor chip and are connected to the conductive layer. The first interconnects include a plurality of transmit signal interconnects each transmitting a distinct signal and a plurality of receive signal interconnects each receiving a distinct signal. The second interconnects are formed over a second zone and are either symmetric with the first interconnects about the y-axis or are identical to the first interconnects. The third interconnects are formed over a third zone and are either symmetric with the first interconnects about an x-axis or are identical to the first interconnects. The fourth interconnects are formed over a fourth zone and are either symmetric with the third interconnects about the y-axis or are identical to the third interconnects.

In another embodiment, a method for manufacturing a system comprises: fabricating a semiconductor chip and forming a plurality of first interconnects over two or more zones of a bottom or top surface of the semiconductor chip. Fabricating the semiconductor chip includes: receiving a chip substrate; forming a chip circuit that perform one or more circuit functions over the chip substrate; and interconnecting chip components of the chip circuit using a conductive layer. Forming the first interconnects includes: arranging the first interconnects in each zone in an array of rows; connecting each first interconnect in a first zone to a respective first interconnect in a fourth zone; and connecting each first interconnect in a second zone to a respective first interconnect in a third zone. The first interconnects from top to bottom rows in the first zone are symmetric with the first interconnects from bottom to top rows in the fourth zone about the y-axis. the first interconnects from top to bottom rows in the second zone are symmetric with the first interconnects from bottom to top rows in the third zone about the y-axis. the first interconnects from top to bottom rows in the second zone are symmetric with the first interconnects from bottom to top rows in the third zone about the y-axis.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system comprising:
a plurality of semiconductor chips stacked on top of each other and including:
a semiconductor chip having a bottom or top surface divided into two or more zones; and
a plurality of first interconnects formed over the zones, wherein:
the first interconnects in each zone are arranged in an array of rows;
each first interconnect in a first zone is connected to a respective first interconnect in a fourth zone;
the first interconnects from top to bottom rows in the first zone are symmetric with the first interconnects from bottom to top rows in the fourth zone about the y-axis;
each first interconnect in a second zone is connected to a respective first interconnect in a third zone; and
the first interconnects from top to bottom rows in the second zone are symmetric with the first interconnects from bottom to top rows in the third zone about the y-axis.

2. The system of claim 1, wherein the interconnects are in the form of micro-bumps, solder balls, copper pillars, a ball grid array (BGA), a combination of metal and dielectric interconnects, other interconnects created by metal-to-metal bonding, dielectric-to-dielectric bonding, tape-automated bonding (TAB), wire bonding, or flip-chip bonding, other suitable interconnects, or combinations thereof.

3. The system of claim 1, wherein:
the first zone is beside the second zone and above the third zone; and
the fourth zone is below the second zone and beside the third zone.

4. The system of claim 1, further comprising:
the first interconnects at a top-left corner of the bottom or top surface of the semiconductor chip;
a plurality of second interconnects at a top-right corner and symmetric with the first interconnects about the y-axis;
a plurality of third interconnects at a bottom-left corner and symmetric with the first interconnects about an x-axis; and
a plurality of fourth interconnects at a bottom-right corner and symmetric with the third interconnects about the y-axis.

5. The system of claim 1, further comprising:
the first interconnects at a top-left corner of the bottom or top surface of the semiconductor chip;
a plurality of second interconnects at a top-right corner and identical to the first interconnects;
a plurality of third interconnects at a bottom-left corner and identical to the first interconnects; and
a plurality of fourth interconnects at a bottom-right corner and identical to the first interconnects.

6. The system of claim 1, further comprising:
the first interconnects at a top-left corner of the bottom or top surface of the semiconductor chip;
a plurality of second interconnects at a top-right corner and symmetric with the first interconnects about the y-axis;
a plurality of third interconnects at a bottom-left corner and identical to the first interconnects; and
a plurality of fourth interconnects at a bottom-right corner and identical to the second interconnects.

7. The system of claim 1, further comprising a plurality of supply voltage (VDD) interconnects each configured to receive a supply voltage (VDD) and defining and the first, second, third, and fourth zones.

8. The system of claim 1, further comprising a plurality of reference voltage (VSS) interconnects each configured to receive a reference voltage (VSS) or connected to ground and dividing each zone into a plurality of sub-zones.

9. A semiconductor chip comprising:
a chip substrate;
a chip circuit fabricated over the chip substrate and configured to perform one or more circuit functions;
a conductive layer interconnecting chip components of the chip circuit;
a plurality of first interconnects formed over a first zone of a bottom or top surface of the semiconductor chip and connected to the conductive layer, wherein the first interconnects include:
a plurality of transmit signal interconnects each configured to transmit a distinct signal; and
a plurality of receive signal interconnects each configured to receive a distinct signal;
a plurality of second interconnects formed over a second zone and either symmetric with the first interconnects about the y-axis or identical to the first interconnects;
a plurality of third interconnects formed over a third zone and either symmetric with the first interconnects about an x-axis or identical to the first interconnects; and
a plurality of fourth interconnects formed over a fourth zone and either symmetric with the third interconnects about the y-axis or identical to the third interconnects.

10. The semiconductor chip of claim 9, wherein:
the first zone is at top-left corner of the bottom or top surface of the semiconductor chip;
the second zone is at top-right corner;
the third zone is at bottom-left corner; and
the fourth zone is at bottom-right.

11. The semiconductor chip of claim 9, wherein:
the second interconnects are symmetric with the first interconnects about the y-axis;
the third interconnects are symmetric with the first interconnects about the x-axis; and
the fourth interconnects are symmetric with the third interconnects about the y-axis.

12. The semiconductor chip of claim 9, wherein the second interconnects, the third interconnects, and the fourth interconnects are identical to the first interconnects.

13. The semiconductor chip of claim 9, wherein:
the second interconnects are symmetric with the first interconnects about the y-axis;
the third interconnects are identical to the first interconnects; and
the fourth interconnects are symmetric with the third interconnects about the y-axis.

14. The semiconductor chip of claim 9, further comprising a plurality of supply voltage (VDD) interconnects each configured to receive a supply voltage (VDD) and dividing the first zone into two or more sub-zones.

15. The semiconductor chip of claim 9, further comprising a plurality of reference voltage (VSS) interconnects each configured to receive a reference voltage (VSS) or connected to ground and dividing each sub-zone into quadrants.

16. A method for manufacturing a system, the method comprising:
fabricating a semiconductor chip including:
receiving a chip substrate;
forming a chip circuit that perform one or more circuit functions over the chip substrate; and
interconnecting chip components of the chip circuit using a conductive layer; and
forming a plurality of first interconnects over two or more zones of a bottom or top surface of the semiconductor chip including:
arranging the first interconnects in each zone in an array of rows;
connecting each first interconnect in a first zone to a respective first interconnect in a fourth zone, wherein the first interconnects from top to bottom rows in the first zone are symmetric with the first interconnects from bottom to top rows in the fourth zone about the y-axis; and
connecting each first interconnect in a second zone to a respective first interconnect in a third zone, wherein the first interconnects from top to bottom rows in the second zone are symmetric with the first interconnects from bottom to top rows in the third zone about the y-axis.

17. The method of claim 16, further comprising forming a plurality of supply voltage (VDD) interconnects that each configured to receive a supply voltage (VDD) and defining the first, second, third, and fourth zones.

18. The method of claim 16, further comprising forming a plurality of reference voltage (VSS) that each configured to receive a reference voltage (VSS) or connected to ground and dividing each zone into sub-zones.

19. The method of claim 16, further comprising forming one or more clock signal interconnects each configured to transmit a clock signal and lying along the y-axis.

20. The method of claim 16, further comprising forming one or more clock signal interconnects each configured to receive a clock signal and lying along the y-axis.
